(19) United States
(12) Patent Application Publication
(10) Pub. No.: US 2011/0127654 A1
(43) Pub. Date: Jun. 2, 2011

(54) Semiconductor Package and Manufacturing Methods Thereof

(75) Inventors: Chaofu Weng, Tainan City (TW); John Richard Hunt, Chandler, AZ (US); Li Chuan Tsai, Daliao Township (TW); Yi Ting Wu, Chiayi City (TW); Chieh-Chen Fu, Kaohsiung City (TW); Ying-Te Ou, Kaoshiung (TW)

(73) Assignee: ADVANCED SEMICONDUCTOR ENGINEERING, INC..,, KAOSIUNG (TW)

(21) Appl. No.: 12/955,782

(22) Filed: Nov. 29, 2010

(30) Foreign Application Priority Data
Nov. 27, 2009 (TW) 98140649

(51) Int. Cl. H01L 23/552; H01L 21/56

(52) U.S. Cl. 257/660; 438/124; 257/E21.502; 257/E23.114

(57) ABSTRACT

A semiconductor package and manufacturing methods thereof are provided. In one embodiment, the semiconductor package includes a die, a shield, a package body, and a redistribution layer. The die has an active surface and an inactive surface. The shield is disposed over the inactive surface of the die. The package body encapsulates the die and a first portion of the shield, where a first surface of the package body is substantially coplanar with the active surface of the die. The redistribution layer is disposed on the active surface of the die and on portions of the first surface of the package body.

### CROSS-REFERENCE TO RELATED APPLICATION

The present application claims the benefit of Taiwan Application No. 98140649, filed on Nov. 27, 2009, the subject matter of which is incorporated herein by reference.

### BACKGROUND OF THE INVENTION

1. Field of the Invention

The present invention generally relates to electronic device packaging. More particularly, the present invention relates to a semiconductor package and manufacturing methods thereof.

2. Description of Related Art

Semiconductor devices have become progressively more complex, driven at least in part by the demand for smaller sizes and enhanced processing speeds. While the benefits of smaller sizes and enhanced processing speeds are apparent, these characteristics of semiconductor devices also can create problems.

In conventional wafer-level packaging, semiconductor devices within a wafer are packaged prior to singulation of the wafer. As such, conventional wafer-level packaging can be restricted to a fan-in configuration, namely electrical contacts and other components of a resulting semiconductor device package are restricted to an area defined by a periphery of a semiconductor device. Any component disposed outside of the periphery of the semiconductor device typically is not supported and typically is removed upon singulation. The restriction of a fan-in configuration presents challenges as device sizes continue to shrink.

Also, higher clock speeds can involve more frequent transitions between signal levels, which, in turn, can lead to a higher level of electromagnetic emissions at higher frequencies or shorter wavelengths. Electromagnetic emissions can radiate from a source semiconductor device, and can be incident upon neighboring semiconductor devices. If the level of electromagnetic emissions at a neighboring semiconductor device is sufficiently high, these emissions can adversely affect the operation of that semiconductor device. This phenomenon is sometimes referred to as electromagnetic interference (“EMI”). Smaller sizes of semiconductor devices can further exacerbate EMI by providing a higher density of those semiconductor devices within an overall electronic system, and, thus, a higher level of undesired electromagnetic emissions at a neighboring semiconductor device.

It is against this background that a need arose to develop the semiconductor device packages and related methods described herein.

### SUMMARY OF THE INVENTION

In one innovative aspect, embodiments of the invention relate to a semiconductor package. In one embodiment, the semiconductor package includes a die, a shield, a package body, and a redistribution layer. The die has an active surface and an inactive surface. The shield is disposed over the inactive surface of the die. The package body encapsulates the die and a first portion of the shield, where a first surface of the package body is substantially coplanar with the active surface of the die. The redistribution layer is disposed on the active surface of the die and on portions of the first surface of the package body.

In another embodiment, the semiconductor package includes a die, a shield, a package body, and a redistribution layer. The die has an active surface. The shield extends over the die, and comprises a lateral section and a central section. The package body encapsulates the die but exposes the active surface. The package body also encapsulates portions of the lateral section of the shield. The central portion of the shield is disposed on an exterior surface of the package body. The redistribution layer is disposed on the active surface of the die and a first surface of the package body.

In another innovative aspect, embodiments of the invention relate to a method of manufacturing a semiconductor package. In one embodiment, the method includes: (a) providing a die having an active surface; (b) placing a metal structure over the die, the metal structure including a mesh defining a plurality of openings; (c) encapsulating the metal structure and the die with an encapsulant such that the active surface of the die, portions of the metal structure, and portions of the encapsulant form a substantially coplanar surface, where the molding material traverses the plurality of openings to encapsulate the die; and (d) forming a redistribution layer on the substantially coplanar surface, the redistribution layer electrically connected to the active surface of the die.

### BRIEF DESCRIPTION OF THE DRAWINGS

FIG. 1 is a cross-sectional view of a semiconductor package, according to an embodiment of the invention;

FIG. 2 is a top view of the lateral section of the electromagnetic interference shield of FIG. 1, according to an embodiment of the invention;

FIGS. 3A through 3M are cross-sectional views illustrating the method of manufacturing the semiconductor package of FIG. 1, according to an embodiment of the invention;

FIG. 4 is a top view of a lateral section of an electromagnetic interference shield of a semiconductor package, according to an embodiment of the invention;

FIG. 5 is a cross-sectional view of a semiconductor package, according to an embodiment of the invention;

FIG. 6 is a cross-sectional view of a semiconductor package, according to an embodiment of the invention;

FIGS. 7A through 7M show a top view (FIG. 7A) and cross-sectional views (FIGS. 7B through 7M) illustrating the method of manufacturing the semiconductor package of FIG. 6, according to an embodiment of the invention;

FIG. 8 is a cross-sectional view of a semiconductor package, according to an embodiment of the invention;

FIGS. 9A through 9D are cross-sectional views illustrating the method of manufacturing the semiconductor package of FIG. 8, according to an embodiment of the invention;

FIG. 10 is a cross-sectional view of a semiconductor package, according to an embodiment of the invention;

FIG. 11 is a cross-sectional view of a semiconductor package, according to an embodiment of the invention;

FIG. 12 is a cross-sectional view of a semiconductor package, according to an embodiment of the invention; and

FIGS. 13A through 13C show cross-sectional views illustrating a method of manufacturing the semiconductor package of FIG. 12, according to an embodiment of the invention.

The drawings illustrate embodiments of the invention and, together with the description, serve to explain the principles of some embodiments of the invention. Reference will now be made in detail to some embodiments of the invention, examples of which are illustrated in the accompanying drawings. Wherever possible, the same reference numbers are used in the drawings and the descriptions to refer to the same or like features.

### DETAILED DESCRIPTION OF THE INVENTION

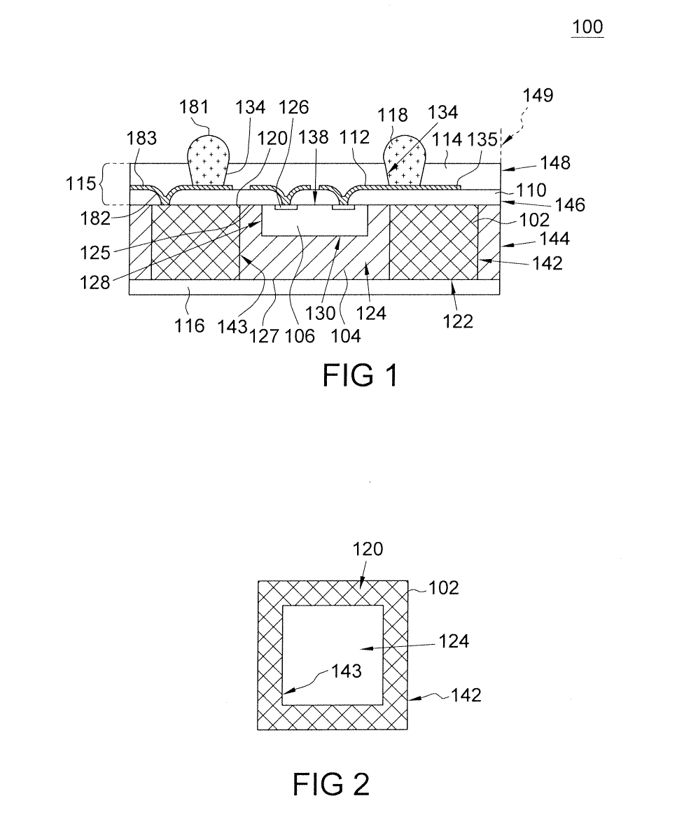

Referring to FIG. 1, a cross-sectional view of a semiconductor package 100 according to an embodiment of the invention is shown. The semiconductor package 100 may be a communication semiconductor package or another type of semiconductor package. The semiconductor package 100 includes an electromagnetic interference shield including a lateral section 102 and a central section 116, a package body 104, a die 106, a redistribution layer 115, an electrical contact 118, and an electrical contact 181. The redistribution layer 115 includes a first dielectric layer 110, a conductive layer 112, and a second dielectric layer 114. The thickness of the lateral section 102 may be substantially equal to the thickness of the package body 104.

FIG. 2 is a top view of the lateral section 102 of the electromagnetic interference shield of FIG. 1, according to an embodiment of the invention. Referring to both FIG. 1 and FIG. 2, the lateral section 102 includes a first surface 120, a second surface 122 opposite to the first surface 120, a first lateral surface 142, and a second lateral surface 143. The lateral section 102 may define an opening 124, where the second lateral surface 143 is disposed adjacent to the opening 124. The first lateral surface 142 may face away from the opening 124, while the second lateral surface 143 may face the opening 124. The lateral section 102 may be a closed ring surrounding the opening 124. Alternatively, the lateral section 102 may include a plurality of separate metal blocks that form the second lateral surface 143 of the lateral section 102. The die 106 is disposed at least partially within the opening 124. Since the lateral section 102 is encapsulated and isolated from the environment, damage to the lateral section 102 caused by the environment can be reduced as a result, and the lateral section 102 need not be made of antioxidant materials. For example, the lateral section 102 may be made from inexpensive metal materials such as copper, aluminum, or non-antioxidant metals.

In the embodiment of FIGS. 1 and 2, the central section 116 is disposed adjacent to the second surface 122 (an exterior surface of the package body 104) and covers the opening 124. The lateral section 102 and the central section 116 may surround the die 106, which can effectively prevent electromagnetic interference. The central section 116 may be a conductive coating formed by spray coating, sputtering, application of conductive ink, or some other suitable approach. Alternatively, the central section 116 may be a conductive film and/or foil laminated or otherwise attached to the lateral section 102 by an adhesive layer. An exposed surface of the central section 116 may be further coated with a non-conductive coating or film (not shown), which may protect against unintended electrostatic discharge (ESD).

The die 106 includes a plurality of die bond pads 126, and includes an active surface 138 on which the die bond pads 126 are disposed. In one embodiment, portions of the active surface 138 may be covered by a passivation layer (not shown) that exposes the die bond pads 126. The die 106 further includes a back surface 130 opposite to the active surface 138, and a side surface 128. The back surface 130 and the side surface 128 may be referred to as inactive surfaces. The lateral section 102 and/or the central section 116 may be disposed over inactive surfaces of the die 106. The redistribution layer 115 is electrically connected to the active surface 138 of the die 106. The die 106 may be an integrated circuit or other type of semiconductor die, such as a micro electro-mechanical system (MEMS). While one semiconductor die is shown in the package 100, it is contemplated that additional semiconductor dies can be included in semiconductor packages for other implementations.

The package body 104 may be formed in the opening 124, such that the package body 104 encapsulates the die 106 and a first portion of the electromagnetic interference shield, such as the lateral section 102. For example, the package body 104 may cover the side surface 128 of the die 106 and the first lateral surface 142 of the lateral section 102. The package body 104 may be exposed on an external periphery of the semiconductor package 100. In one embodiment, the package body 104 covers the back surface 130 of the die 106, and exposes the plurality of pads 126 of the die 106. The package body 104 may further cover the second lateral surface 143 of the lateral section 102. In one embodiment, the package body 104 may cover the second surface 122 of the lateral section 102. The package body 104 may have a first surface 125 and a second surface 127 opposite to the first surface 125. The first surface 125 may be substantially coplanar with the active surface 138 of the die 106, and may be substantially coplanar with the first surface 120 of the lateral section 102. The second surface 127 may be substantially coplanar with the central section 116, and with the second surface 122 of the lateral section 102.

In one embodiment, the semiconductor package 100 is a wafer level package (WLP) formed by chip-redistribution encapsulant level package technology. After having been singulated and separated, the die 106 on the wafer can be re-distributed on the carrier to form various structures such as a redistribution layer 115. The redistribution layer 115 is electrically connected to the die 106, and provides electrical pathways as well as mechanical stability and protection against environmental conditions. The redistribution layer 115 may be disposed on the active surface 138 of the die 106 and on the first surface 125 of the package body 104. The redistribution layer 115 may include only the conductive layer 112, or may be multi-layered. In the illustrated embodiment, the redistribution layer 115 is multi-layered and includes the first dielectric layer 110, the second dielectric layer 114, and the conductive layer 112 that is at least partially sandwiched by the dielectric layers 110 and 114.

In general, each of the dielectric layers 110 and 114 can be formed from a dielectric material that is polymeric or non-polymeric. For example, at least one of the dielectric layers 110 and 114 can be formed from polyimide, polybenzoxazole, benzocyclobutene, or a combination thereof. The dielectric layers 110 and 114 can be formed from the same dielectric material or different dielectric materials. For certain implementations, at least one of the dielectric layers 110 and 114 can be formed from a dielectric material that is photoimageable or photoactive, thereby reducing manufacturing cost and time by allowing patterning using photolithography. The first dielectric layer 110 may be formed adjacent to the active surface 138 of the die 106, and adjacent to the first surface 120 of the lateral section 102. The first dielectric layer 110 defines a plurality of first apertures 132 (illustrated in FIG. 31) for correspondingly exposing the pads 126.

The conductive layer 112 may be formed adjacent to the first dielectric layer 110. In one embodiment, the conductive layer 112 may be a pre-patterned conductive layer. The conductive layer 112 may include a first part 135 and a second part 183. In one embodiment, the first part 135 is electrically connected to the pads 126. The second part 183 may be electrically connected to the lateral section 102, such as through an aperture 182 in the first dielectric layer 110 for exposing the lateral section 102. The second part 183 may be a ground portion of the conductive layer 112.

The second dielectric layer 114 may be formed adjacent to the conductive layer 112 to protect the conductive layer 112. The second dielectric layer 114 defines a plurality of second apertures 134 for exposing the conductive layer 112. In one embodiment, the electrical contacts 118 are formed on a portion of the second apertures 134 for electrically connecting to the first part 135 of the conductive layer 112. The electrical contacts 181 are formed on a remaining portion of the second apertures 134 for electrically connecting to the lateral section 102. The electrical contacts 181 may form the ground path for connecting the lateral section 102, and hence the EMI shield, to ground. The electrical contacts 118 and 181 may include a conductive material, such as solder balls, gold studs, or copper pillars. Moreover, the second apertures 134 could have a plurality of solder ball pad layers (not illustrated), such as under bump metallization (UBM), formed therein for enhancing the cohesion of the electrical contacts 118 and 181.

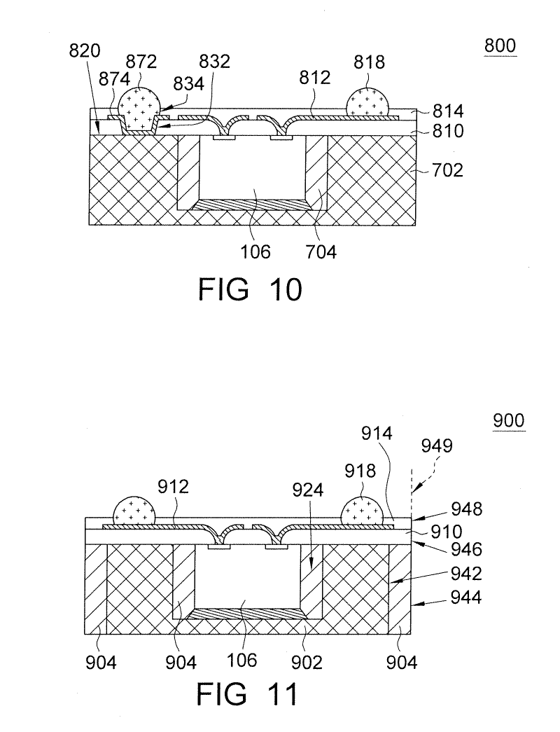

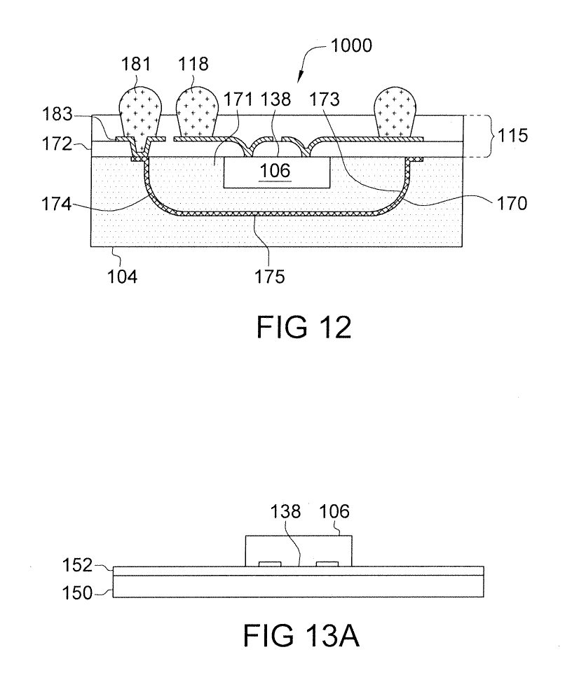

In the embodiment illustrated in FIG. 1, the electrical contact 181 is disposed in the second aperture 134 but not in the first aperture 182. Alternatively, the electrical contact 181 may be disposed in both the first aperture 182 and the second aperture 134 (see FIGS. 10 and 12).

The first dielectric layer 110 includes an outer sidewall 146, and the second dielectric layer 148 includes an outer sidewall 148. In one embodiment, a third lateral surface 144 of the package body 104, the outer sidewall 146, and the outer sidewall 148 are aligned and define a plane 149.

The periphery of the redistribution layer 115, as defined by the outer sidewalls 146 and 148, has a greater lateral extent than the periphery of the die 106, thereby allowing the package 100 to be implemented with a fan-out configuration, namely components of the package 100 can be disposed within as well as outside of an area defined by the periphery of the die 106.

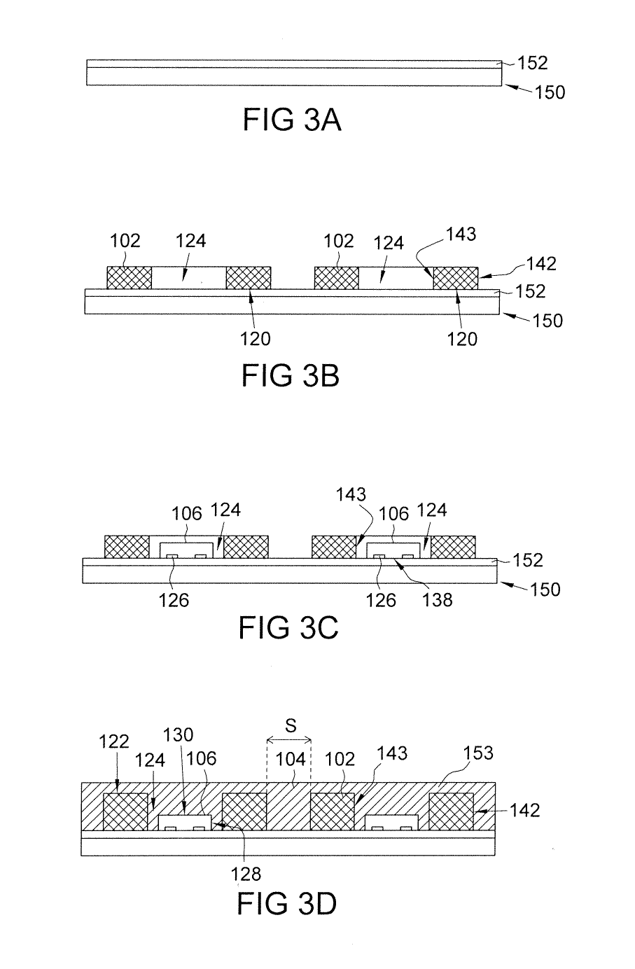

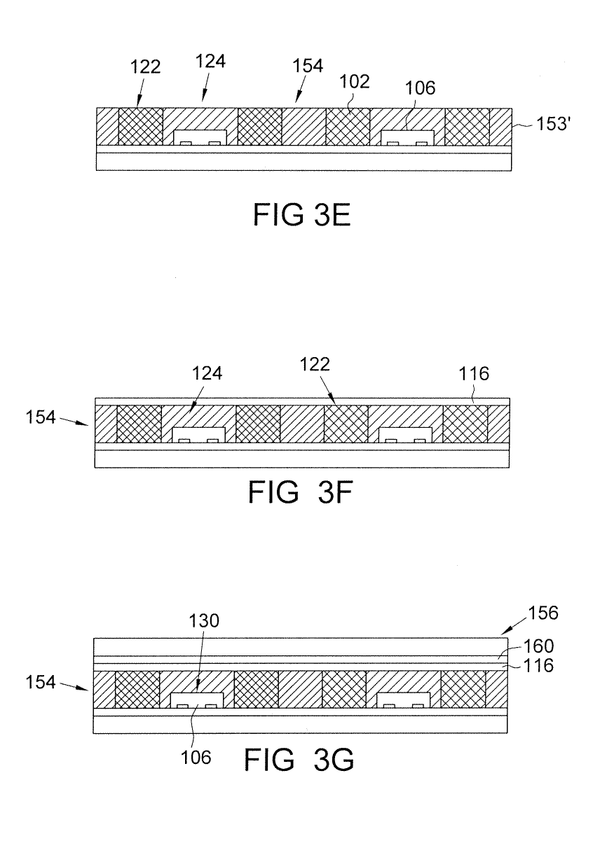

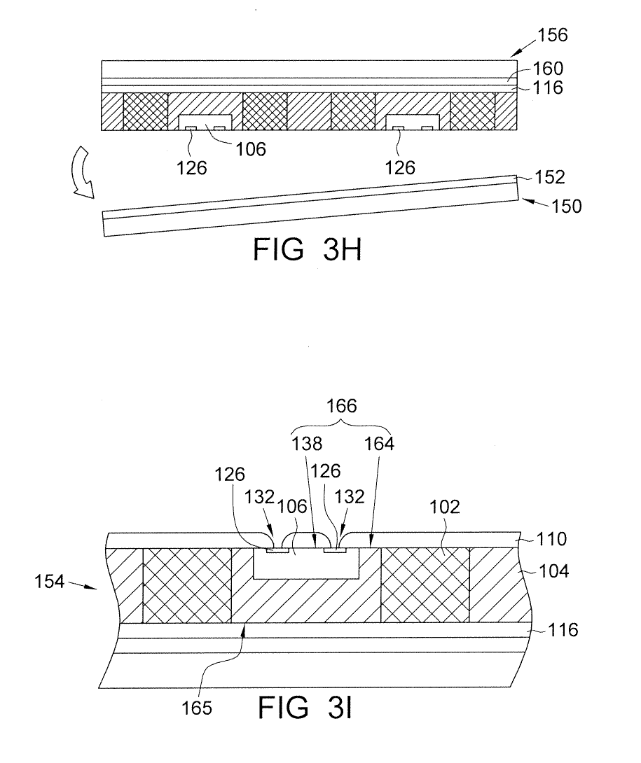

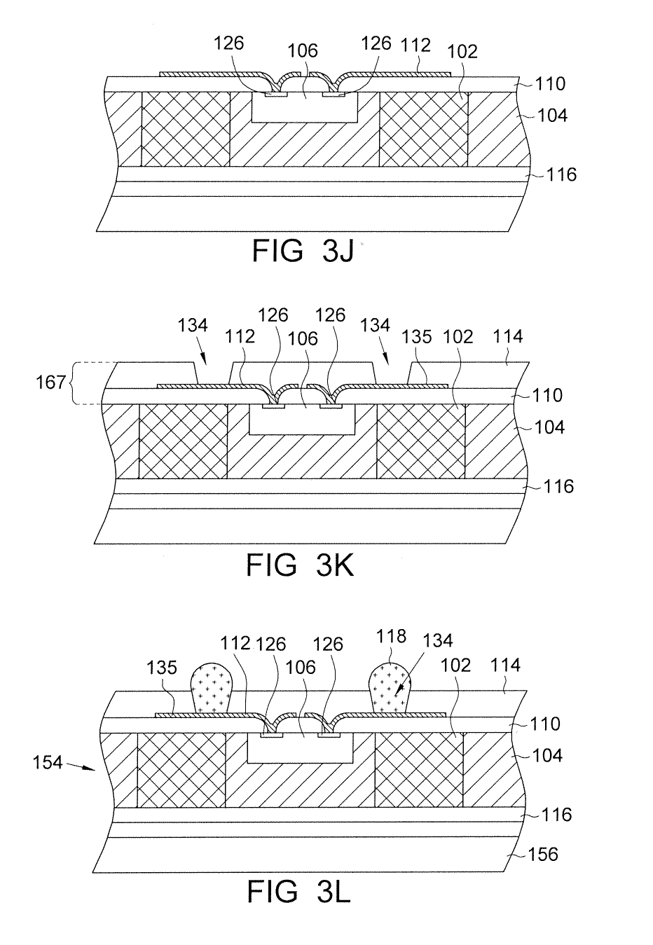

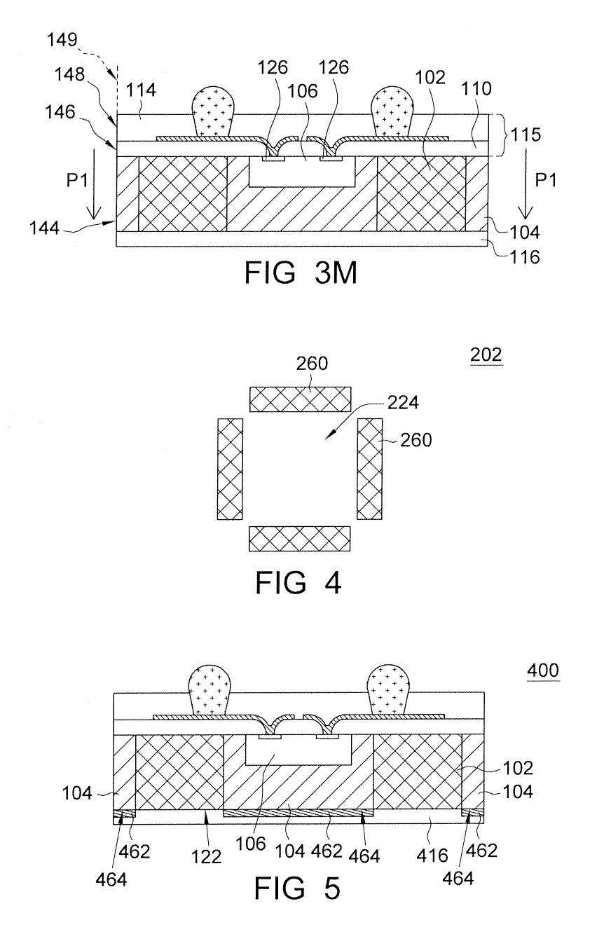

FIGS. 3A through 3M show cross-sectional views illustrating the method of manufacturing the semiconductor package 100 of FIG. 1, according to an embodiment of the invention. As illustrated in FIG. 3A, a first carrier 150 and an adhesive layer 152 disposed adjacent to the first carrier 150 are provided.

As illustrated in FIG. 3B, a plurality of lateral sections 102 are disposed adjacent to the adhesive layer 152. The first surface 120 of the lateral section 102 is connected to the adhesive layer 152 adjacent to the first carrier 150. Each lateral section 102 defines an opening 124, where the first lateral surface 142 included in each lateral section 102 faces away from the opening 124, and where the second lateral surface 143 included in each lateral section 102 faces toward the opening 124. The opening 124 can be formed in the lateral section 102 by way of pressing, laser processing, or other approaches known to one of ordinary skill in the art. The opening 124 may be a via hole. The lateral sections 102 are separately disposed on the adhesive layer 152 adjacent to the first carrier 150.

As illustrated in FIG. 3C, a plurality of dies 106 are correspondingly disposed adjacent to the second lateral surface 143 of each of the plurality of lateral sections 102, and adjacent to the first carrier 150. Each die 106 may be disposed within a corresponding opening 124. The die 106 is connected to the adhesive layer 152 of the first carrier 150, wherein the pads 126 and the active surface 138 of the die 106 face the first carrier 150. In one embodiment, the dies 106 may be separated and removed from a wafer, and then redistributed on the first carrier 150.

Alternatively, the plurality of dies 106 may be disposed on the adhesive layer 152 adjacent to the first carrier 150. The plurality of lateral sections 102 may then be disposed adjacent to the adhesive layer 152 adjacent to the first carrier 150.

As illustrated in FIG. 3D, the side surface 128 and the back surface 130 of the die 106, the first lateral surface 142 and the second surface 122 of the lateral section 102, and the second lateral surface 143 of each of the lateral sections 102 are covered with an encapsulant 153. The encapsulant 153 may be a molding material, commonly referred to as mold compound. The encapsulant 153 may substantially fill each of the openings 124. The encapsulant 153 may also substantially fill a space S between two adjacent lateral sections 102.

As illustrated in FIG. 3E, a portion of the encapsulant 153 formed on the second surface 122 of each of the lateral sections 102 and above each of the openings 124 is removed to expose each of the second surfaces 122. The portion of the encapsulant 153 may be removed through chemical mechanical polishing (CMP), or through other approaches known to one of ordinary skill in the art. The remaining portion 153′ of the encapsulant 153, the dies 106, and the lateral sections 102 form a molded structure 154.

As illustrated in FIG. 3F, a central section 116 is formed adjacent to the second surface 122 of each of the lateral sections 102 and adjacent to the molded structure 154.

As illustrated in FIG. 3G, the molded structure 154 and the central section 116 are disposed adjacent to an adhesive layer 160 that is adjacent to a second carrier 156. The central section 116 may be connected to the adhesive layer 160 adjacent to the second carrier 156, such that the back surface 130 of each of the dies 106 faces the second carrier 156.

As illustrated in FIG. 3H, the first carrier 150 is removed to expose the pads 126 of each of the dies 106. The molded structure 154 is then inverted as illustrated in FIG. 3I so that the pads 126 of each of the dies 106 face upward.

For simplicity, the manufacturing operations of FIG. 3I through FIG. 3L are illustrated for a portion of the structure of FIG. 3H corresponding to one of the dies 106. For ease of presentation, the manufacturing operations of FIG. 3I through FIG. 3L are described with reference to the semiconductor package 100 of FIG. 1. It is contemplated that the manufacturing operations of FIG. 3I through FIG. 3L can be similarly carried out for multiple dies 106.

Referring to FIG. 3I, the active surface 138 of the die 106 and a first surface 164 of a portion of the molded structure 154 corresponding to the package body 104 define a front surface 166. The first dielectric layer 110 is formed adjacent to the front surface 166 and may also be formed adjacent to the lateral section 102. The first dielectric layer 110 defines a plurality of apertures 132 that expose the pads 126 of the die 106. The first dielectric layer 110 may also define apertures 182 (see FIG. 1) that expose the lateral section 102. An exterior surface 165 of the portion of the molded structure 154 corresponding to the package body 104 is adjacent to the central section 116.

As illustrated in FIG. 3J, the conductive layer 112 is formed adjacent to the first dielectric layer 110. The first part 135 of the conductive layer 112 is electrically connected to the pads 126 of the die 106. In one embodiment, the conductive layer 112 may be a pre-patterned conductive layer. The second part 183 (see FIG. 1) of the conductive layer 112 may be electrically connected to the lateral section 102.

As illustrated in FIG. 3K, the second dielectric layer 114 is formed adjacent to the conductive layer 112, where the second dielectric layer 114 defines a plurality of apertures 134 that expose portions of the conductive layer 112. A redistribution layer 167 including the redistribution layer 115 (see FIG. 1) includes the first dielectric layer 110, the conductive layer 112, and the second dielectric layer 114.

As illustrated in FIG. 3L, a plurality of electrical contacts 118, such as solder balls, are formed in corresponding apertures 134 and are electrically connected to the first portion 135 of the conductive layer 112. Electrical contacts 181 (see FIG. 1), such as solder balls, can be formed in other corresponding apertures 134 and are electrically connected to the second part 183 (see FIG. 1) of the conductive layer 112. The second carrier 156 is then removed.

As illustrated in FIG. 3M, a plurality of semiconductor packages 100 of FIG. 2 are separated by singulating along cutting paths P1. Each cutting path P1 passes through the first dielectric layer 110, the second dielectric layer 114, and the molded structure 154 (see FIG. 3L) to form the redistribution layer 115 and the package body 104. In one embodiment, the third lateral surface 144 of the package body 104, the outer sidewall 146 of the first dielectric layer 110 and the outer sidewall 148 of the second dielectric layer 114 are aligned and define the plane 149 after singulation, as previously described with reference to FIG. 2.

Referring to FIG. 4, a top view of a lateral section 202 of an electromagnetic interference shield of a semiconductor package according to an embodiment of the invention is shown. The lateral section 202 may include one or more metal blocks 260 or discrete segments of either a linear form (as shown) or a non-linear form (not shown). For example, the lateral section 202 may include one, two, three, four, or more than four metal blocks 260.

In one embodiment, four metal blocks 260 are separately disposed to define an opening 224. The four metal blocks 260 may be arranged in a rectangle. Alternatively, the metal blocks 260 may be arranged to form another shape, such as a triangle or a polygon. The metal blocks 260 may be positioned in such as way as to maximize the shielding effect for EMI. The positioning can be determined by modelling and/or testing the shield with respect to specific EMI parameters such as wavelength and/or frequency.

A semiconductor package including the lateral section 202 is similar to the semiconductor package 100 previously described with reference to FIG. 2 through FIG. 3, except that the lateral section 202 may have aspects that differ from the lateral section 102 (see FIG. 2).

Referring to FIG. 5, a cross-sectional view of a semiconductor package 400 according to an embodiment of the invention is shown. The semiconductor package 400 is similar to the semiconductor package 100 previously described with reference to FIG. 2 through FIG. 3, except that the semiconductor package 400 further includes a connection layer 462, which may also be referred to as an adhesion or cohesion layer.

In one embodiment, the connection layer 462 is formed adjacent to the package body 104, and may be made from a polymer material. The connection layer 462 is disposed between the electromagnetic interference shield 416 and the package body 104 to enhance the cohesion between the electromagnetic interference shield 416 and the package body 104. Alternatively, the connection layer 462 may be formed adjacent to both the package body 104 and the lateral section 102, which may save the cost of patterning the connection layer 462.

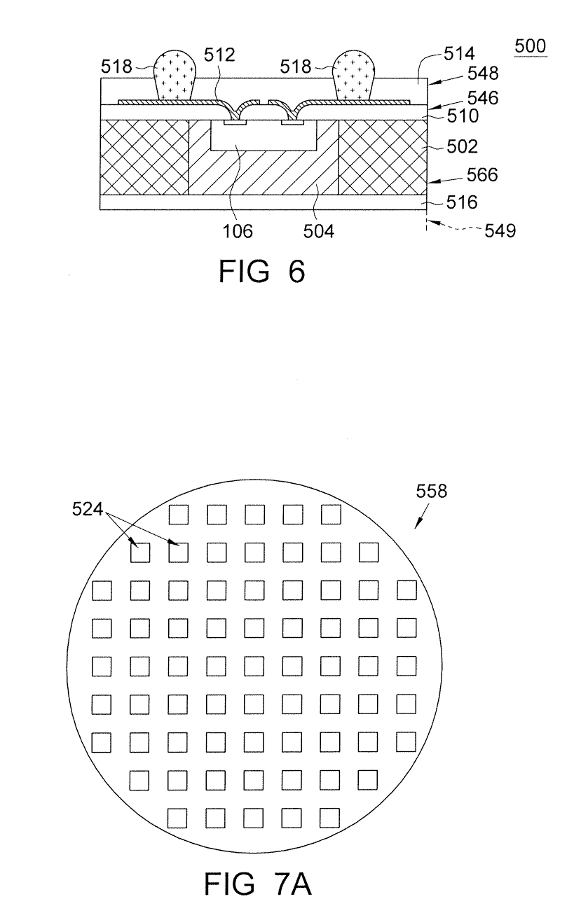

A method of manufacturing the semiconductor package 400 of FIG. 5, according to an embodiment of the invention, is in various respects similar to the method of FIG. 3. Manufacturing of the semiconductor package 400 first proceeds similarly to the operations illustrated in FIGS. 3A through 3E. Then, a connection layer 462 (see FIG. 6) is formed on an exterior surface 464 of a molded structure (not illustrated). The molded structure includes one or more interconnected package bodies similar to the package body 104, each package body corresponding to a die 106. Then, an electromagnetic interference shield 416 (see FIG. 6) is formed on the second surface 122 of the lateral sections 102 and the connection layer 462. Manufacturing of the semiconductor package 400 then proceeds similarly to the operations illustrated in FIGS. 3G through 3M.

Referring to FIG. 6, a cross-sectional view of a semiconductor package 500 according to an embodiment of the invention is shown. The semiconductor package 500 is similar to the semiconductor package 100 previously described with reference to FIG. 2 through FIG. 3, except that the first lateral surface 566 of the lateral section 502 of an electromagnetic shield of the semiconductor package 500 is exposed on an outer lateral periphery of the semiconductor package 500.

The semiconductor package 500 includes a lateral section 502, a package body 504, a die 106, a first dielectric layer 510, a conductive layer 512, a second dielectric layer 514, a plurality of electrical contacts 518 and an electromagnetic interference shield 516.

The first dielectric layer 510, the conductive layer 512, the second dielectric layer 514, and the electrical contacts 518 are similar to the first dielectric layer 110, the conductive layer 112, the second dielectric layer 114, and electrical contacts 118 of the semiconductor package previously described with reference to FIG. 2 through FIG. 3, and are not further described here.

The first lateral surface 566 of the lateral section 502, an outer sidewall 546 of the first dielectric layer 510, and an outer sidewall 548 of the second dielectric layer 514 may be aligned and may define a plane 549.

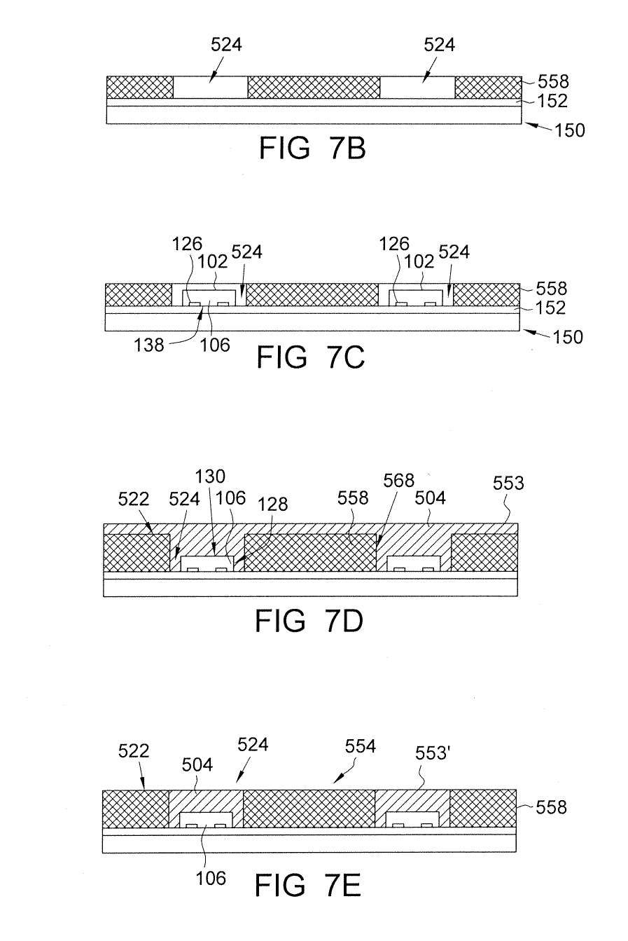

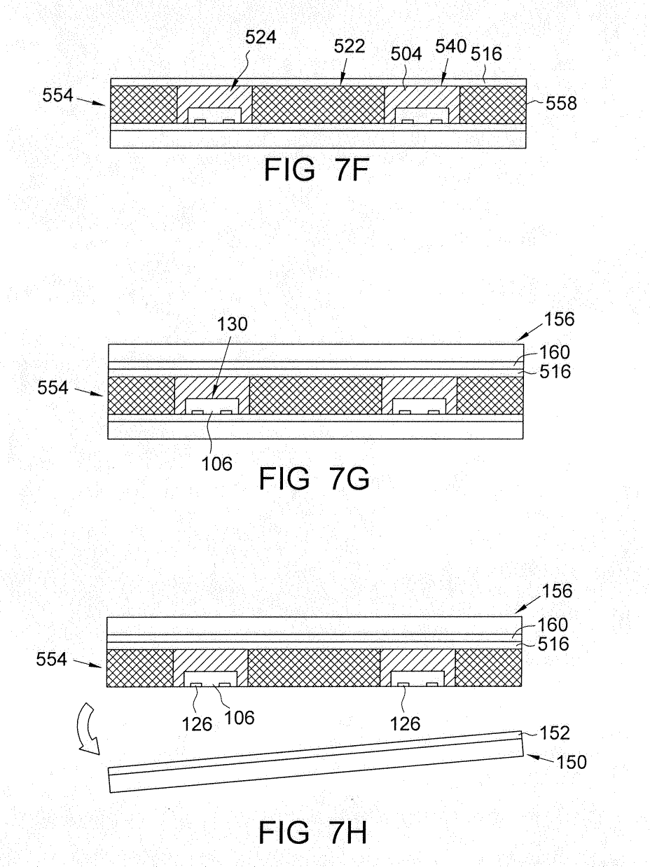

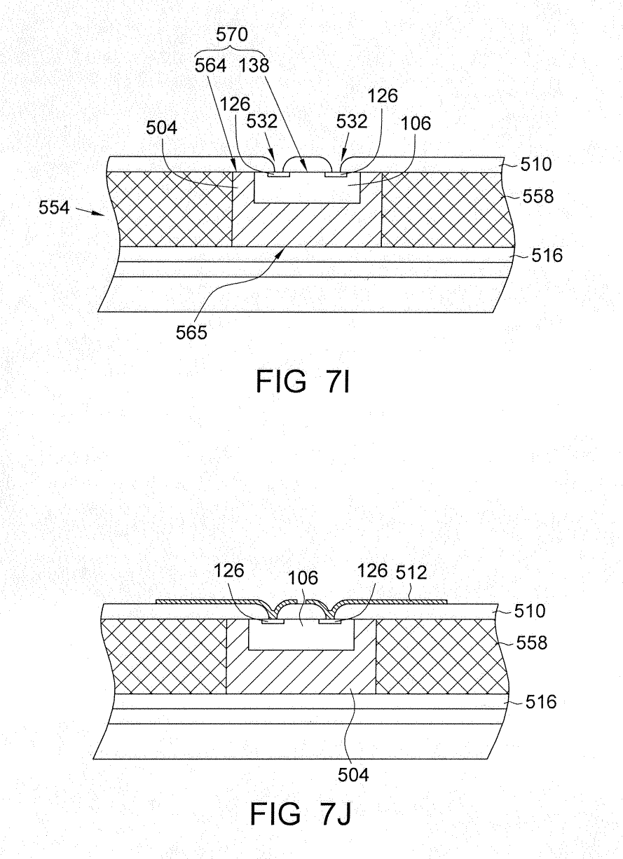

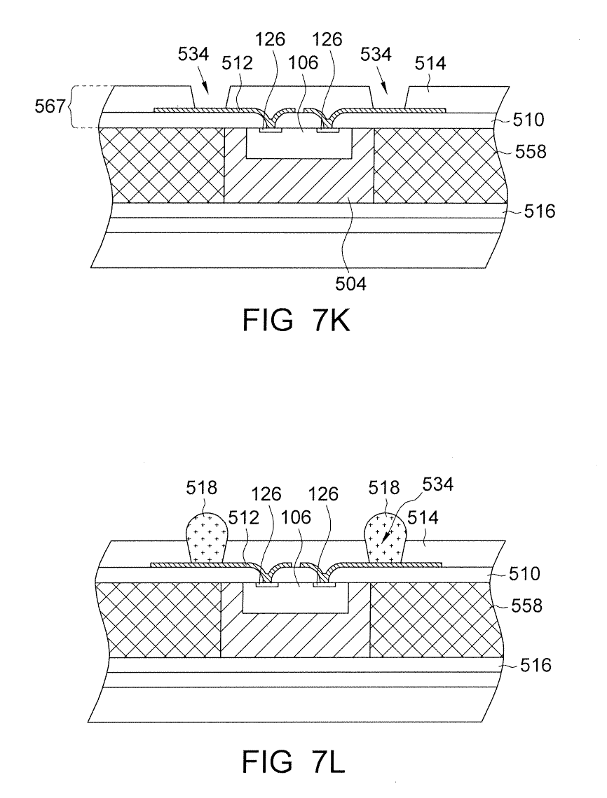

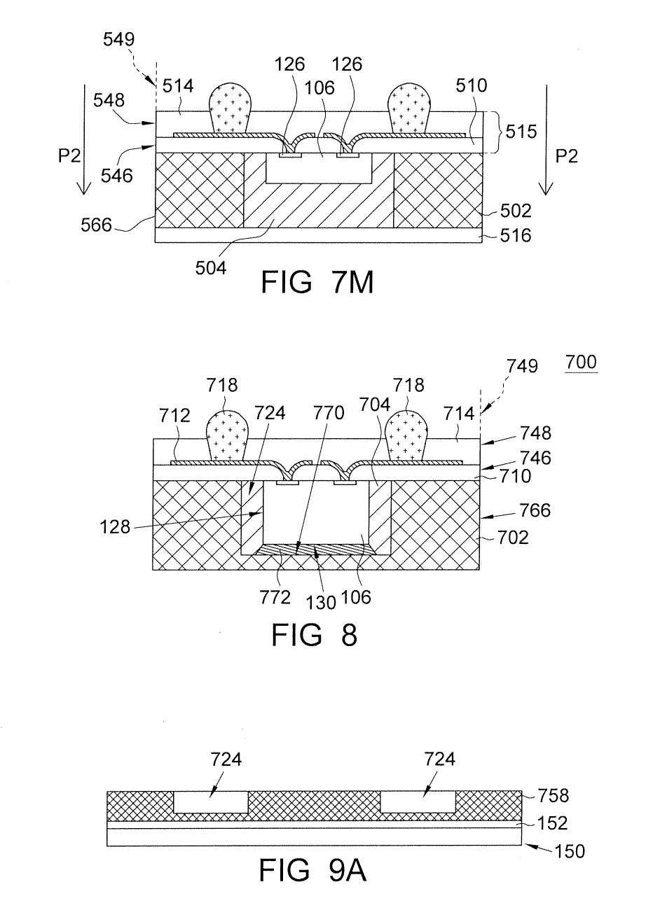

FIGS. 7A through 7M show a top view (FIG. 7A) and cross-sectional views (FIGS. 7B through 7M) illustrating the method of manufacturing the semiconductor package 500 of FIG. 6, according to an embodiment of the invention.

As illustrated in FIGS. 7A and 7B, a continuous metal structure 558 (a shield matrix 558) includes multiple lateral sections 502 (see FIG. 6). Each lateral section 502 may be a contiguous element extending around a lateral periphery of a die 106. The metal structure 558 defines a plurality of openings 524, such as via holes. The openings 524 may be formed in a similar manner as described previously for the openings 124 (see FIG. 3B). The openings 524 may be aligned in a two-dimensional grid pattern, or alternatively may be spaced irregularly. The metal structure 558 is disposed on the adhesive layer 152 adjacent to the first carrier 150.

As illustrated in FIG. 7C, a plurality of dies 106 are disposed in the openings 524 and adjacent to the first carrier 150, wherein each die 106 includes a plurality of pads 126 and an active surface 138 facing the adhesive layer 152 of the first carrier 150.

As illustrated in FIG. 7D, the side surface 128 and the back surface 130 of the die 106, the first lateral surface 568 of the metal structure 558, and the first surface 522 of the metal structure 558 are covered with an encapsulant 553. The encapsulant 553 may be a molding material. The encapsulant 553 may substantially fill each of the openings 524.

As illustrated in FIG. 7E, a portion of the encapsulant 553 formed on the first surface 522 of the metal structure 558 and above each of the openings 524 is removed to expose the first surface 522. The portion of the encapsulant 553 may be removed through chemical mechanical polishing (CMP), or through other approaches known to one of ordinary skill in the art. The remaining portion 553′ of the encapsulant 553, the dies 106, and the metal structure 558 form a molded structure 554.

As illustrated in FIG. 7F, an electromagnetic interference shield 516 is formed adjacent to the first surface 522 of the metal structure 558, and adjacent to the molded structure 554. The electromagnetic interference shield 516 may cover the openings 524.

Moreover, in another implementation, the electromagnetic interference shield 516 is not necessarily formed in the semiconductor package (not illustrated).

As illustrated in FIG. 7G, the molded structure 554 and the electromagnetic interference shield 516 are disposed adjacent to the adhesive layer 160 that is adjacent to the second carrier 156. The electromagnetic interference shield 516 may be connected to the adhesive layer 160 adjacent to the second carrier 156, such that the back surface 130 of each of the dies 106 faces the second carrier 156.

As illustrated in FIG. 7H, the first carrier 150 is removed to expose the pads 126 of each of the dies 106. The molded structure 554 is then inverted as illustrated in FIG. 7I so that the pads 126 of each of the dies 106 face upward.

For simplicity, the manufacturing operations of FIG. 7I through FIG. 7L are illustrated for a portion of the structure of FIG. 7H corresponding to one of the dies 106. For ease of presentation, the manufacturing operations of FIG. 7I through FIG. 7L are described with reference to the semiconductor package 500 of FIG. 6. It is contemplated that the manufacturing operations of FIG. 7I through FIG. 7L can be similarly carried out for multiple dies 106.

Referring to FIG. 7I, the active surface 138 of the die 106 and a first surface 564 of a portion of the molded structure 554 corresponding to the package body 504 define a front surface 570. The first dielectric layer 510 is formed adjacent to the front surface 570 and the active surface 138 of the die 106. In one embodiment, the first dielectric layer 510 may also be formed adjacent to the metal structure 558. The first dielectric layer 510 defines a plurality of apertures 532 that expose the pads 126 of the die 106. The first dielectric layer 510 may also define apertures 182 (see FIG. 1) that expose the metal structure 558. A second surface 565 of the portion of the molded structure 554 corresponding to the package 504 is adjacent to the electromagnetic interference shield 516.

As illustrated in FIG. 7J, a first part of the conductive layer 512 is formed adjacent to the first dielectric layer 510 and is electrically connected to the pads 126 of the die 106. In one embodiment, the conductive layer 512 may be a pre-patterned conductive layer. A second part of the conductive layer 512 (similar to the second part 183 of the conductive layer 112 illustrated in FIG. 1) may be electrically connected to the metal structure 558.

As illustrated in FIG. 7K, the second dielectric layer 514 is formed adjacent to the conductive layer 512, where the second dielectric layer 514 defines a plurality of apertures 534 that expose portions of the conductive layer 512. A redistribution layer 567 includes the first dielectric layer 510, the conductive layer 512, and the second dielectric layer 514.

As illustrated in FIG. 7L, a plurality of electrical contacts 518, such as solder balls, are formed in corresponding apertures 534 and are electrically connected to the first part of the conductive layer 512. Electrical contacts similar to electrical contacts 181 illustrated in FIG. 1, such as solder balls, can be formed in other corresponding apertures 534 and are electrically connected to the second part of the conductive layer 512 (similar to the second part 183 of the conductive layer 112 illustrated in FIG. 1). The second carrier 156 is removed.

As illustrated in FIG. 7M, a plurality of semiconductor packages 500 of FIG. 6 are separated by singulating along cutting paths P2. Each cutting path P2 passes through the first dielectric layer 510, the second dielectric layer 514, and the metal structure 558 (see FIG. 7L) to form a redistribution layer 515, the lateral section 502, and the package body 504. In one embodiment, the first lateral surface 566 of the lateral section 502, the outer sidewall 546 of the first dielectric layer 510, and the outer sidewall 548 of the second dielectric layer 514 are aligned and define the plane 549 after singulation, as previously described with reference to FIG. 6.

Moreover, in another implementation (not illustrated), the connection layer 462 of FIG. 5 could also be formed in the semiconductor package 500 of FIG. 6. The formation of the connection layer 462 is similar to that previously described with reference to FIG. 5.

Referring to FIG. 8, a cross-sectional view of a semiconductor package 700 according to an embodiment of the invention is shown. The semiconductor package 700 is similar to the semiconductor package 500 previously described with reference to FIG. 6 through FIG. 7, except that the electromagnetic interference shield 702 defines cavities 724. A surface 770 of the metal structure 758 defines a bottom of each corresponding cavity 724. The cavities 724 could be manufactured by way of, for example, laser drilling or mechanical cutting.

The semiconductor package 700 includes the electromagnetic interference shield 702, a package body 704, a die 106, a first dielectric layer 710, a conductive layer 712, a second dielectric layer 714, and a plurality of electrical contacts 718.

The first dielectric layer 710, the conductive layer 712, the second dielectric layer 714, and the electrical contacts 718 are similar to the first dielectric layer 510, the conductive layer 512, the second dielectric layer 514, and electrical contacts 518 of the semiconductor package 500 previously described with reference to FIG. 6 through FIG. 7, and are not further described here.

The first lateral surface 766 of the electromagnetic interference shield 702, an outer sidewall 746 of the first dielectric layer 710, and an outer sidewall 748 of the second dielectric layer 714 may be aligned and may define a plane 749.

The back surface 130 of the die 106 is disposed on the surface 770 that defines the bottom of the cavity 724. The die 106 may be tightly fixed on the surface 770 by a die attach film (DAF) 772. The side surface 128 of the die 106 is encapsulated by the package body 704. In this embodiment, the cavity 724 is a recess in the electromagnetic interference shield 702, so both the back surface 130 and the side surface 128 of the die 106 are encapsulated by the electromagnetic interference shield 702 for effectively preventing electromagnetic interference.

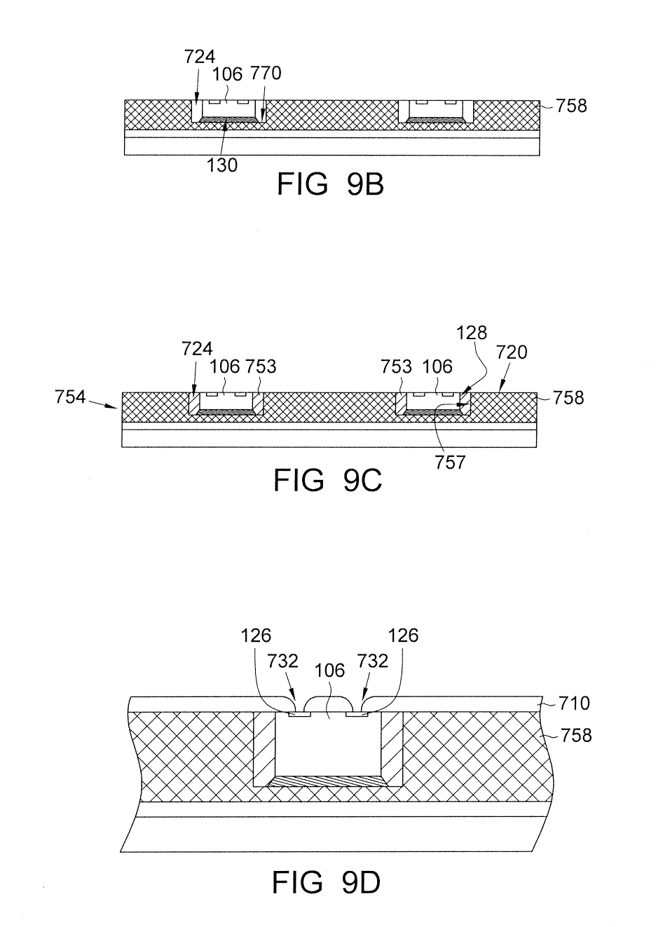

FIGS. 9A through 9D show cross-sectional views illustrating the method of manufacturing the semiconductor package 700 of FIG. 8, according to an embodiment of the invention.

As illustrated in FIG. 9A, a continuous metal structure 758 includes multiple electromagnetic interference shields 702 (see FIG. 8). The metal structure 758 defines the plurality of cavities 724. The cavities 724 may be aligned in a two-dimensional grid pattern, or alternatively may be spaced irregularly. The metal structure 758 is disposed on the adhesive layer 152 adjacent to the first carrier 150.

As illustrated in FIG. 9B, a plurality of dies 106 are disposed at least partially within the cavities 724. The back surface 130 of each of the dies 106 is adjacent to and faces a surface 770 of the metal structure 758 that defines a bottom of each corresponding cavity 724.

As illustrated in FIG. 9C, the side surface 128 of each of the dies 106 and a lateral surface 757 of the metal structure 758 that defines a sidewall of each corresponding cavity 724 is covered with an encapsulant 753 to form a molded structure 754. The encapsulant 753 may be a molding material. The encapsulant 753 may substantially fill each of the cavities 724.

In another embodiment, a first surface 720 of the metal structure 758 and the pads 126 of each of the dies 106 can also be covered with the encapsulant 753. In this embodiment, a plurality of apertures in the encapsulant 753 for exposing the pads 126 are formed by, for example, an exposing and developing process.

As illustrated in FIG. 9D, the first dielectric layer 710 is formed on the die 106 and the metal structure 758. For simplicity, the manufacturing operations of FIG. 9D are illustrated for a portion of the structure of FIG. 9C corresponding to one of the dies 106. The first dielectric layer 710 has a plurality of apertures 732 that expose the pads 126 of the die 106.

In another embodiment, a first surface 720 of the metal structure 758 and the pads 126 of each of the dies 106 can also be covered with the encapsulant 753. Then, the apertures 732 can pass through the encapsulant 753 to expose the pads 126 of the die 106.

Manufacturing of the semiconductor package 700 then proceeds similarly to the operations illustrated in FIGS. 7J through 7L. Then, the first carrier 150 and the adhesive layer 152 are removed. Singulation (similar to that illustrated in FIG. 7M), is then performed to obtain the semiconductor package 700.

Referring to FIG. 10, a cross-sectional view of a semiconductor package 800 according to an embodiment of the invention is shown. The semiconductor package 800 is similar to the semiconductor package 700 previously described with reference to FIG. 8 through FIG. 9, except that the semiconductor package 800 further includes a ground electrical contact 872, such as a ground solder ball, electrically connected to the electromagnetic interference shield 702.

The semiconductor package 800 includes an electromagnetic interference shield 702, a package body 704, a die 106, a first dielectric layer 810, a conductive layer 812, a second dielectric layer 814, an electrical contact 818, and a ground electrical contact 872.

The first dielectric layer 810 is formed adjacent to a first surface 820 of the electromagnetic interference shield 702. The first dielectric layer 810 further defines a first aperture 832 that exposes a part of the electromagnetic interference shield 702. The conductive layer 812 further includes a ground portion 874 correspondingly formed in the first aperture 832 that electrically connects to the electromagnetic interference shield 702. The second dielectric layer 814 further has a second aperture 834 that exposes the ground portion 874 of the conductive layer 812. The ground electrical contact 872 is formed in the second aperture 834 for electrically connecting to the electromagnetic interference shield 702.

In one embodiment, the electromagnetic interference shield 702 may electrically connect a ground end (not illustrated) so that the semiconductor package 800 is enhanced for preventing electromagnetic interference. For example, the ground electrical contacts 872 may be electrically connected to an external circuit, such as a ground end on a circuit board, so that the electromagnetic interference shield 702 is electrically connected to the ground end of the external circuit.

The manufacturing method of the semiconductor package 800 of FIG. 10 is similar to the manufacturing method of the semiconductor package 700 previously described with reference to FIG. 8 through FIG. 9, and is not further described here.

One of ordinary skill in the technology of the invention will understand that the technical features of grounding the metal block disclosed in the embodiment of FIG. 10 can also be adapted to the semiconductor packages of any of the other embodiments of semiconductor packages disclosed herein.

Referring to FIG. 11, a cross-sectional view of a semiconductor package 900 according to an embodiment of the invention is shown. The semiconductor package 900 is similar to the semiconductor package 700 previously described with reference to FIG. 8 through FIG. 9, except that the package body 904 is exposed on an external periphery of the semiconductor package 900.

The semiconductor package 900 includes an electromagnetic interference shield 902, a package body 904, the die 106, a first dielectric layer 910, a conductive layer 912, a second dielectric layer 914, and a plurality of electrical contacts 918.

The first dielectric layer 910, the conductive layer 912, the second dielectric layer 914, and solder balls 918 of the present embodiment are similar to the first dielectric layer 710, the conductive layer 712, the second dielectric layer 714 and the electrical contacts 718 of the semiconductor package 700 previously described with reference to FIG. 8 through FIG. 9, and are not further described here.

The first lateral surface 942 of the electromagnetic interference shield 902 is encapsulated by the package body 904. The third lateral surface 944 of the package body 904, an outer sidewall 946 of the first dielectric layer 910, and an outer sidewall 948 of the second dielectric layer 914 are aligned and define a plane 949.

The manufacturing method of the semiconductor package 900 of FIG. 11 is similar to the method illustrated in FIG. 9, except for the operations illustrated in FIGS. 9A, 9C, and the singulation operation (similar to that illustrated in FIG. 7M) performed to obtain the semiconductor package 700. These operations are further described below for the semiconductor package 900.

In contrast to the operation illustrated in FIG. 9A, there are a plurality of electromagnetic interference shields 902 disposed separately, where each of the plurality of electromagnetic interference shields 902 defines a cavity 924.

In contrast to the operation illustrated in FIG. 9C, the encapsulant is similar to the encapsulant 753, but is also formed in the space between the electromagnetic interference shields 902.

In contrast to the singulation operation (similar to that illustrated in FIG. 7M), a plurality of semiconductor packages 900 as illustrated in FIG. 11 are separated along a cutting path (not illustrated). The cutting path passes through the first dielectric layer 910, the second dielectric layer 914, and the encapsulant. After singulation, the third lateral surface 944 of the package body 904, the outer sidewall 946 of the first dielectric layer 910, and the outer sidewall 948 of the second dielectric layer 914 may be aligned and define the plane 949.

Referring to FIG. 12, a cross-sectional view of a semiconductor package 1000 according to an embodiment of the invention is shown. The semiconductor package 1000 includes portions similar to the semiconductor package 100 of FIG. 1, including the semiconductor die 106 having the active surface 138, the package body 104, the redistribution layer 115, the electrical contacts 118, and the electrical contacts 181. An electromagnetic interference (EMI) shield 170 is disposed over the die 106 and defines a cavity 171 between the shield 170 and the die 106. The package body 104 encapsulates the shield 170 and the die 106 such that the package body 104 fills the cavity 171. The shield has a first lateral surface 173 adjacent to the cavity, and a second lateral surface 174. The package body 174 covers the first lateral surface 173 and the second lateral surface 174. In one embodiment, the active surface 138, portions of the shield 170, and portions of the package body 104 define a front surface 172. The front surface 172 may be a substantially coplanar surface. The redistribution layer 115 is disposed adjacent to the front surface 172, and is electrically connected to the active surface 138 of the die 106.

In one embodiment, the shield 170 may be covered by the package body 104 except for the portions of the shield 170 on the front surface 172. Since the shield 170 is encapsulated and isolated from the environment, the shield 170 need not be made of antioxidant materials. For example, the shield 170 may be made from inexpensive metal materials such as copper, aluminum, or non-antioxidant metals.

In one embodiment, the shield 170 defines openings 175, so that the shield 170 is porous. The shield 170 may be a wire mesh. The mesh pitch of the shield 170 can be configured to protect against specific EMI wavelengths and/or other parameters such as frequency. These specific EMI parameters can be determined by modelling and testing the devices in the semiconductor package 1000 and/or the printed circuit boards on which the semiconductor package 1000 is placed. For example, the mesh pitch of the shield 170 can be chosen to be a fraction of a wavelength corresponding to the highest frequency present in the semiconductor package 1000.

The die 106 may be an integrated circuit or other type of semiconductor die, such as a micro electro-mechanical system (MEMS). While the shield 170 is shown as disposed over a single semiconductor die 106, it is contemplated that the shield 170 may be disposed over multiple semiconductor dies in other implementations.

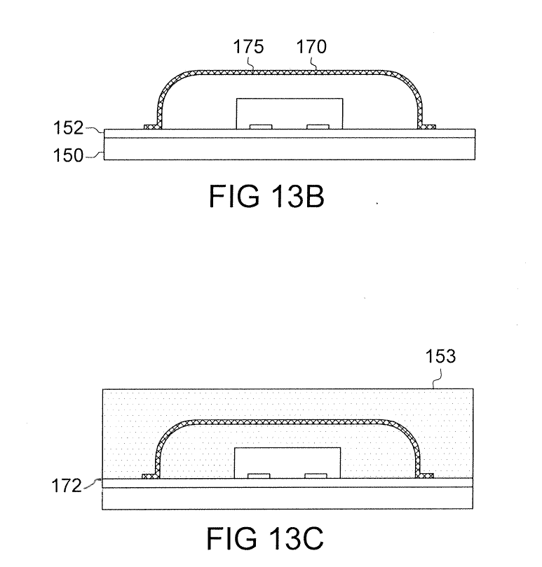

FIGS. 13A through 13C show cross-sectional views illustrating a method of manufacturing the semiconductor package 1000 of FIG. 12, according to an embodiment of the invention. In FIG. 13A, one or more dies 106 are disposed adjacent to the adhesive layer 152 of the carrier 150 (previously described in FIG. 3A), where the active surface 138 of the die 106 faces the carrier 150. In FIG. 13B, the EMI shield 170 is disposed over the die 106 such that portions of the shield 170 are connected to the adhesive 152. In FIG. 13C, a molding material is then applied to form the molded structure 153. The molding material traverses the openings 175 in the EMI shield 170 to encapsulate the shield 170 and the die 106. The method of manufacturing the semiconductor package 1000 may then continue with operations similar to those illustrated in FIGS. 3F through 3M.

According to the semiconductor package and the manufacturing method thereof disclosed in the above embodiments of the invention, the electromagnetic interference shield surrounds the die for effectively preventing electromagnetic interference. In an embodiment, since the whole of the electromagnetic interference shield is encapsulated and isolated from the environment, the electromagnetic interference shield can be made from an inexpensive material such as metal such as copper, aluminum, or a non-antioxidant metal.

While the invention has been described and illustrated with reference to specific embodiments thereof, these descriptions and illustrations do not limit the invention. It should be understood by those skilled in the art that various changes may be made and equivalents may be substituted without departing from the true spirit and scope of the invention as defined by the appended claims. The illustrations may not be necessarily be drawn to scale, and manufacturing tolerances may result in departure from the artistic renditions herein. There may be other embodiments of the present invention which are not specifically illustrated. Thus, the specification and the drawings are to be regarded as illustrative rather than restrictive. Additionally, the drawings illustrating the embodiments of the present invention may focus on certain major characteristic features for clarity. Furthermore, modifications may be made to adapt a particular situation, material, composition of matter, method, or process to the objective, spirit and scope of the invention. All such modifications are intended to be within the scope of the claims appended hereto. In particular, while the methods disclosed herein have been described with reference to particular operations performed in a particular order, it will be understood that these operations may be combined, sub-divided, or re-ordered to form an equivalent method without departing from the teachings of the invention. Accordingly, unless specifically indicated herein, the order and grouping of the operations are not limitations of the invention.

What is claimed is:

1. A semiconductor package, comprising:
a die having an active surface and an inactive surface;
a shield disposed over the inactive surface of the die;
a package body encapsulating the die and a first portion of the shield wherein a first surface of the package body is substantially coplanar with the active surface of the die; and
a redistribution layer disposed on the active surface of the die and on portions of the first surface of the package body.

2. The semiconductor package of claim 1, wherein the shield includes a mesh portion that is encapsulated by the package body.

3. The semiconductor package of claim 2, wherein a pitch of the mesh portion is configured to protect against electromagnetic interference with specific parameters.

4. The semiconductor package of claim 1, wherein the redistribution layer includes a dielectric layer and a conductive layer having a first part and a second part, wherein the first part of the conductive layer is electrically connected to the active surface of the die.

5. The semiconductor package of claim 4, wherein the second part of the conductive layer includes a ground portion that extends through the dielectric layer and that electrically connects to the shield.

6. The semiconductor package of claim 1, wherein a second surface of the package body opposite to the first surface is substantially coplanar with a second portion of the shield.

7. The semiconductor package of claim 1, wherein the first surface of the package body is substantially coplanar with the first portion of the shield.

8. The semiconductor package of claim 1, wherein the shield has a side surface that is exposed on a lateral periphery of the semiconductor package.

9. A semiconductor package, comprising:
a die having an active surface;
a shield extending over the die, the shield comprising a lateral section and a central section;
a package body encapsulating the die but exposing the active surface, and encapsulating portions of the lateral section of the shield, the central section of the shield disposed on an exterior surface of the package body; and
a redistribution layer disposed on the active surface of the die and a first surface of the package body.

10. The semiconductor package of claim 9, wherein the lateral section of the shield is a contiguous element extending around a lateral periphery of the die.

11. The semiconductor package of claim 9, wherein the lateral section of the shield includes a plurality of discrete elements positioned around a lateral periphery of the die.

12. The semiconductor package of claim 9, wherein the central section of the shield is a conductive coating.

13. The semiconductor package of claim 9, wherein the central section of the shield is a conductive film attached to the lateral section by an adhesive layer.

14. The semiconductor package of claim 9, wherein the redistribution layer includes a dielectric layer and a conductive layer having a first part and a second part, wherein the first part of the conductive layer is electrically connected to the active surface of the die.

15. The semiconductor package of claim 14, wherein the second part of the conductive layer includes a ground portion that extends through the dielectric layer and that electrically connects to the shield.

16. The semiconductor package of claim 9, wherein the lateral section of the shield is exposed on an exterior surface of the semiconductor package.

17. The semiconductor package of claim 9, wherein the shield includes a mesh portion that is encapsulated by the package body.

18. A method of manufacturing a semiconductor package, comprising:
providing a die having an active surface;
placing a metal structure over the die, the metal structure including a mesh defining a plurality of openings;
encapsulating the metal structure and the die with an encapsulant such that the active surface of the die, portions of the metal structure, and portions of the encapsulant form a substantially coplanar surface, wherein the molding material traverses the plurality of openings to encapsulate the die; and
forming a redistribution layer on the substantially coplanar surfacc, the redistribution layer electrically connected to the active surface of the die.

19. The method of claim 18, wherein forming the redistribution layer includes forming a dielectric layer and forming a conductive layer having a first portion and a second portion, wherein the first portion of the conductive layer is electrically connected to the active surface of the die.

20. The method of claim 19, further comprising:
forming an aperture in the dielectric layer, the aperture exposing the metal structure;
wherein forming the second portion of the conductive layer includes forming a ground portion in the aperture that electrically connects to the metal structure.
